(19) United States
(12) Patent Application Publication
(10) Pub. No.: US 2025/0046597 A1
(43) Pub. Date: Feb. 6, 2025

(54) SUBSTRATE TREATING METHOD, SUBSTRATE MANUFACTURING METHOD, AND SUBSTRATE TREATING APPARATUS

(71) Applicant: SEMES CO., LTD., Cheonan-si (KR)

(72) Inventors: Hee Hwan KIM, Sejong-si (KR); Bok Kyu LEE, Cheonan-si (KR); Young Hun LEE, Asan-si (KR)

(73) Assignee: SEMES CO., LTD., Cheonan-si (KR)

(21) Appl. No.: 18/735,356

(22) Filed: Jun. 6, 2024

(30) Foreign Application Priority Data
Aug. 3, 2023 (KR) 10-2023-0101343

(51) Int. Cl. H01L 21/02; B08B 3/04; B08B 3/08; B08B 7/00

(52) U.S. Cl. CPC H01L 21/02057; B08B 3/041; B08B 3/08; B08B 7/0021; B08B 2203/007

(57) ABSTRACT

Disclosed is a method of treating a substrate, the method including: a first pre-wet operation of supplying a first pre-wet liquid to a rotating substrate; a second pre-wet operation of supplying a second pre-wet liquid having a temperature different from the first pre-wet liquid to the rotating substrate, the second pre-wet operation being performed after the first pre-wet operation; and a chemical treatment operation of supplying a chemical that is a liquid of a different type from the first pre-wet liquid and the second pre-wet liquid to the rotating substrate, the chemical treatment operation being performed after the second pre-wet operation.

### CROSS-REFERENCE TO RELATED APPLICATIONS

This application claims priority to and the benefit of Korean Patent Application No. 10-2023-0101343 filed in the Korean Intellectual Property Office on Aug. 3, 2023, the entire contents of which are incorporated herein by reference.

### TECHNICAL FIELD

The present invention relates to a substrate treating method, a substrate manufacturing method, and a substrate treating apparatus, and more particularly to a substrate treating method, a substrate manufacturing method, and a substrate treating apparatus for treating a substrate by supplying a solution into a substrate.

### BACKGROUND ART

To manufacture semiconductor devices, a desired pattern is formed on a substrate, such as a wafer, through various processes such as photography, etching, ashing, ion implantation, and thin film deposition. Each process involves the use of various treatment solutions, treatment gas, and particles and process byproducts are generated during the process progress. Cleaning processes are performed before and after each process to remove these particles and process by-products from the substrate.

The cleaning process is a process of supplying a liquid chemical to a rotating substrate to remove impurities attached onto the substrate. The cleaning process may involve the supply of a pre-wet liquid prior to the supply of chemicals to aid in the uniform diffusion of chemicals into the substrate and the uniform treatment by the chemicals. Typically, deionized water is used as the pre-wet liquid.

Patterns, which are microstructures, are formed on the substrate. The pre-wet liquid penetrates into the spaces between the patterns and generates microvascular forces. The microvascular force pulls the patterns in the direction close to the pre-wet liquid. Therefore, pattern collapse phenomenon may be generated by the pre-wet liquid. As the surface tension of the pre-wet liquid is larger, the pattern collapse phenomenon may occur easier. Therefore, to prevent pattern collapse phenomenon, isopropyl alcohol, which has smaller surface tension than deionized water, may be used as a pre-wet liquid.

However, as the process has become increasingly sophisticated in recent years, the patterns formed on the substrate have become highly refined. As the pattern has become finer, the pattern collapse phenomenon has occurred by isopropyl alcohol, even when isopropyl alcohol with low surface tension is used as a pre-wet liquid.

### SUMMARY OF THE INVENTION

The present invention has been made in an effort to provide a substrate treating method, a substrate manufacturing method, and a substrate treating apparatus capable of efficiently treating a substrate.

The present invention has also been made in an effort to provide a substrate treating method, a substrate manufacturing method, and a substrate treating apparatus capable of minimizing the collapse of patterns formed on a substrate during a process of cleaning a substrate.

The present invention has also been made in an effort to provide a substrate treating method, a substrate manufacturing method, and a substrate treating apparatus capable of effectively penetrating a pre-wet liquid into the interstitial space of a pattern having a high aspect ratio while minimizing the occurrence of water marks on a substrate due to evaporation of the pre-wet liquid.

The object of the present invention is not limited thereto, and other objects not mentioned will be clearly understood by those of ordinary skill in the art from the following description. An exemplary embodiment of the present invention provides a method of treating a substrate, the method including: a first pre-wet operation of supplying a first pre-wet liquid to a rotating substrate; a second pre-wet operation of supplying a second pre-wet liquid having a temperature different from the first pre-wet liquid to the rotating substrate, the second pre-wet operation being performed after the first pre-wet operation; and a chemical treatment operation of supplying a chemical that is a liquid of a different type from the first pre-wet liquid and the second pre-wet liquid to the rotating substrate, the chemical treatment operation being performed after the second pre-wet operation.

According to the exemplary embodiment, the temperature of the first pre-wet liquid may be higher than the temperature of the second pre-wet liquid.

According to the exemplary embodiment, the first pre-wet liquid may be an organic solvent provided with a temperature higher than room temperature.

According to the exemplary embodiment, the first pre-wet liquid may be an isopropyl alcohol provided with a temperature higher than room temperature.

According to the exemplary embodiment, the first pre-wet liquid may be isopropyl alcohol provided at a temperature of 30° C. to 80° C.

According to the exemplary embodiment, the second pre-wet liquid may be isopropyl alcohol or deionized water.

According to the exemplary embodiment, the second pre-wet liquid may be provided with a temperature of from 10° C. to 25° C.

According to the exemplary embodiment, the temperature of the second pre-wet liquid may be lower than the temperature of the first pre-wet liquid and be higher than the temperature of the chemical.

According to the exemplary embodiment, the method may further include a third pre-wet operation of supplying a third pre-wet liquid different from the second pre-wet liquid to the rotating substrate, the third pre-wet operation being performed between the second pre-wet operation and the chemical treatment operation.

According to the exemplary embodiment, the second pre-wet liquid may be isopropyl alcohol, and the third pre-wet liquid may be deionized water.

According to the exemplary embodiment, a temperature of the third pre-wet liquid may be closer to the temperature of the second pre-wet liquid than the temperature of the first pre-wet liquid.

According to the exemplary embodiment, the temperature of the second pre-wet liquid supplied in the second pre-wet operation may be higher than the temperature of the chemical and be lower than the temperature of the first pre-wet liquid.

According to the exemplary embodiment, the second pre-wet operation may include supplying the second pre-wet liquid at a first temperature to a top surface of the rotating substrate, and supplying the second pre-wet liquid at a second temperature different from the first temperature to a bottom surface of the rotating substrate.

According to the exemplary embodiment, in the second pre-wet operation, the first temperature of the second pre-wet liquid supplied to the top surface of the substrate may be the same as the temperature of the first pre-wet liquid.

According to the exemplary embodiment, the method may further include: a liquid film forming operation of supplying a wet liquid to the rotating substrate to form a liquid film, the liquid film forming operation being performed after the chemical treatment operation; and a drying operation of supplying a supercritical fluid to the substrate on which the liquid film is formed to dry the substrate, the drying operation being performed after the liquid film forming operation.

Another exemplary embodiment of the present invention provides a manufacturing method including: a first pre-wet operation of supplying heated isopropyl alcohol to a patterned wafer to pre-wet the wafer; after the first pre-wet operation, a second pre-wet operation of supplying room temperature isopropyl alcohol or deionized water to the wafer; after the second pre-wet operation, a chemical treatment operation of supplying a chemical to the wafer; and a drying operation of drying the wafer by supplying supercritical fluid to the wafer on which the chemical treatment operation has been performed.

According to the exemplary embodiment, the chemical may be selected from a substance containing a sulfuric acid component, a substance containing ammonia water, a substance containing a hydrofluoric acid component, or a substance containing a phosphoric acid component.

Still another exemplary embodiment of the present invention provides an apparatus for treating a substrate, the apparatus including: a support unit for supporting a substrate; at least one supply unit for supplying a heated first pre-wet liquid to the substrate supported on the support unit, a second pre-wet liquid having a temperature lower than the first pre-wet liquid, and a chemical having a temperature lower than the first pre-wet liquid; and a controller for controlling the support unit and the supply units, in which the controller controls the support unit and the supply units such that any one of the supply units supplies the first pre-wet liquid to the substrate supported on the support unit, any one of the supply units supplies the second pre-wet liquid to the substrate supported on the support unit, and any one of the supply units supplies the chemical to the substrate supported on the support unit.

According to the exemplary embodiment, the first pre-wet liquid and the second pre-wet liquid may be configured to be supplied from a single nozzle.

According to the exemplary embodiment, the first pre-wet liquid and the second pre-wet liquid may be configured to be supplied from different nozzles.

According to the exemplary embodiment of the present invention, it is possible to efficiently treat a substrate.

According to the exemplary embodiment of the present invention, it is possible to minimize collapse of the pattern formed on the substrate during the process of cleaning the substrate.

According to the exemplary embodiment of the present invention, it is possible to effectively penetrate a pre-wet liquid into the interstitial space of a pattern having a high aspect ratio while minimizing the occurrence of water marks on a substrate due to evaporation of the pre-wet liquid.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

FIG. 1 is a top plan view of a substrate treating apparatus according to an exemplary embodiment of the present invention.

FIG. 2 is a diagram illustrating a liquid treating chamber of FIG. 1.

FIG. 3 is a diagram illustrating lines supplying a pre-wet liquid to a first upper nozzle of FIG. 2.

FIG. 4 is a diagram illustrating a drying chamber of FIG. 1.

FIG. 5 is a flowchart illustrating a substrate treating method according to an exemplary embodiment of the present invention.

FIG. 6 is a diagram illustrating the liquid treating chamber performing a first pre-wet operation of FIG. 5.

FIG. 7 is a diagram illustrating the liquid treating chamber performing a second pre-wet operation of FIG. 5.

FIG. 8 is a diagram illustrating the liquid treating chamber performing a third pre-wet operation of FIG. 5.

FIG. 9 is a diagram illustrating the liquid treating chamber performing a chemical treatment operation of FIG. 5.

FIG. 10 is a diagram illustrating the liquid treating chamber performing a liquid film forming operation of FIG. 5.

FIG. 11 is a diagram illustrating the drying chamber performing a drying operation of FIG. 5.

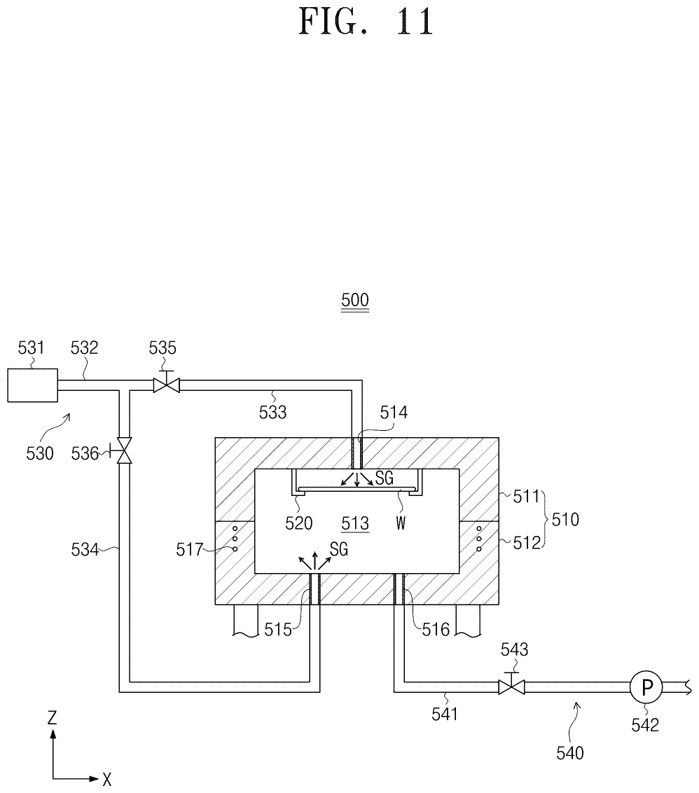

FIG. 12 is a graph illustrating a change in surface tension of the pre-wet liquid according to a change in temperature.

FIG. 13 is an illustrative diagram for illustrating a change in capillary force according to surface tension of the pre-wet liquid.

FIG. 14 is a flowchart illustrating a substrate treating method according to another exemplary embodiment of the present invention.

FIG. 15 is a diagram illustrating a liquid treating chamber according to another exemplary embodiment of the present invention.

FIG. 16 is a diagram illustrating lines supplying a pre-wet liquid to a first upper nozzle according to another exemplary embodiment of the present invention.

FIG. 17 is a diagram illustrating a view of a liquid treating chamber performing a second pre-wet operation according to another exemplary embodiment of the present invention.

FIG. 18 is a diagram illustrating a view of a liquid treating chamber according to another exemplary embodiment of the invention.

### DETAILED DESCRIPTION

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Hereinafter, a substrate W to be treated is described as a wafer. For example, a microstructure, such as a pattern, may be formed on the substrate W that is to be treated. The substrate W to be treated may be a silicon wafer, and the pattern formed on the substrate W may be formed by a process, such as photography, etching, or ion implantation.

A substrate treating method described below may be a manufacturing method for manufacturing a semiconductor device.

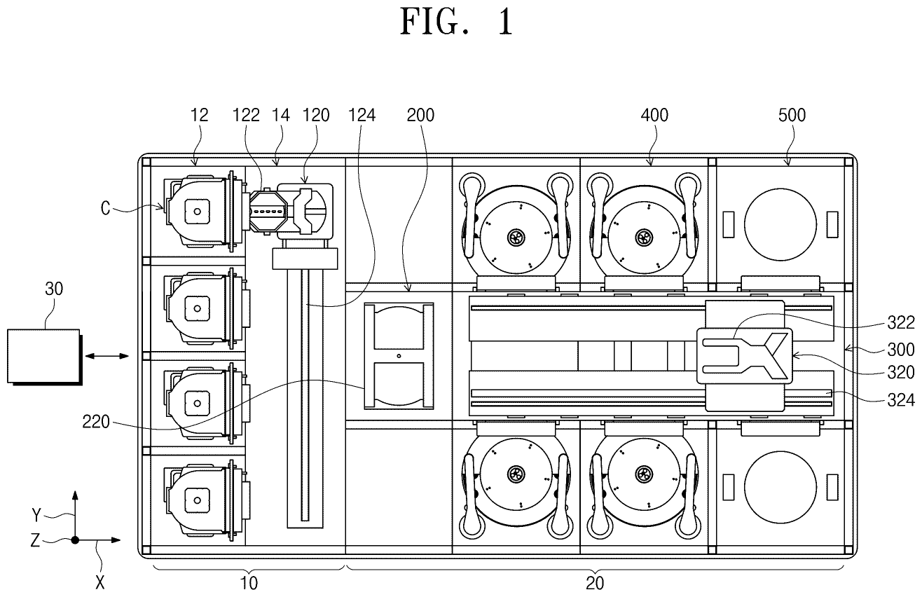

FIG. 1 is a top plan view of a substrate treating apparatus according to an exemplary embodiment of the present invention.

Referring to FIG. 1, the substrate treating apparatus includes an index module 10, a treating module 20, and a controller 30. When viewed from above, the index module 10 and the treating module 20 are disposed along one direction. Hereinafter, the direction in which the index module 10 and the treating module 20 are arranged is referred to as a first direction X, when viewed from above, a direction perpendicular to the first direction X is referred to as a second direction Y, and a direction perpendicular to both the first direction X and the second direction Y is referred to as a third direction Z.

The index module 10 transfers the substrate W from the container C in which the substrate W is accommodated to the treating module 20, and accommodates the substrate W that has been completely treated in the treating module 20 in the container C. A longitudinal direction of the index module 10 is provided in the second direction Y. The index module 10 includes a load port 12 and an index frame 14. Based on the index frame 14, the load port 12 is located at a side opposite to the treating module 20. The container C in which the substrates W are accommodated is placed in the load port 12. A plurality of load ports 12 may be provided, and the plurality of load ports 12 may be disposed along the second direction Y.

As the container C, an airtight container, such as a Front Open Unified Pod (FOUP), may be used. The container C may be placed on the load port 12 by a transport means (not illustrated), such as an overhead transfer, an overhead conveyor, or an automatic guided vehicle, or an operator.

An index robot 120 is provided to the index frame 14. A guide rail 124 of which a longitudinal direction is provided in the second direction Y is provided in the index frame 14, and the index robot 120 may be provided to be movable on the guide rail 124. The index robot 120 includes a hand 122 on which the substrate W is placed, and the hand 122 may be provided to be movable forward and backward directions, rotatable about the third direction Z and movable along the third direction Z. A plurality of hands 122 are provided to be spaced apart in the vertical direction, and the hands 122 may move forward and backward independently of each other.

The treating module 20 includes a buffer unit 200, a transfer chamber 300, a liquid treating chamber 400, and a drying chamber 500. The buffer unit 200 provides a space in which the substrate W loaded into the treating module 20 and the substrate W unloaded from the treating module 20 stay temporarily. The liquid treating chamber 400 performs a liquid treating process of treating the substrate W with a liquid by supplying a liquid onto the substrate W. The drying chamber 500 performs a drying process of removing the liquid residual on the substrate W. The transfer chamber 300 transfers the substrate W between the buffer unit 200, the liquid treating chamber 400, and the drying chamber 500.

The buffer unit 200 includes a plurality of buffers 220 on which the substrate W is placed. The buffers 220 may be disposed to be spaced apart from each other along the third direction Z. The buffer 220 may be a substrate holder that supports the bottom surface of the substrate W. The buffer 220 may be provided in the form of a support shelf that supports the bottom surface of the substrate W.

A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

A longitudinal direction of the transfer chamber 300 may be provided in the first direction X. The buffer unit 200 may be disposed between the index module 10 and the transfer chamber 300. The liquid treating chamber 400 and the drying chamber 500 may be disposed on the side portion of the transfer chamber 300. The liquid treating chamber 400 and the transfer chamber 300 may be disposed along the second direction Y. The drying chamber 500 and the transfer chamber 300 may be disposed along the second direction Y. The buffer unit 200 may be located at one end of the transfer chamber 300.

According to the example, the liquid treating chambers 400 are disposed on both sides of transfer chamber 300, and the drying chambers 500 are disposed on both sides of the transfer chamber 300, and the liquid treating chambers 400 may be disposed closer to the buffer unit 200 than the drying chambers 500. At one side of the transfer chamber 300, the liquid treating chambers 400 may be provided in an arrangement of A×B (each of A and B is 1 or a natural larger than 1) in the first direction X and the third direction Z. Further, at one side of the transfer chamber 300, the drying chambers 500 may be provided in number of C×D (each of C and D is 1 or a natural number larger than 1) in the first direction 92 and the third direction 96. Unlike the above, only the liquid treating chambers 400 may be provided on one side of the transfer chamber 300, and only the drying chambers 500 may be provided on the other side of the transfer chamber 300.

The transfer chamber 300 includes a transfer robot 320. A guide rail 324 of which a longitudinal direction is provided in the first direction X is provided in the transfer chamber 300, and the transfer robot 320 may be provided to be movable on the guide rail 324. The transfer robot 320 includes a hand 322 on which the substrate W is placed, and the hand 322 may be provided to be movable forward and backward directions, rotatable about the third direction Z and movable along the third direction Z. A plurality of hands 322 are provided to be spaced apart in the vertical direction, and the hands 322 may move forward and backward independently of each other.

The controller 30 may control the substrate treating apparatus. The controller 30 may include a process controller formed of a microprocessor (computer) that executes the control of the substrate treating apparatus, a user interface formed of a keyboard in which an operator performs a command input operation or the like in order to manage the substrate treating apparatus, a display for visualizing and displaying an operation situation of the substrate treating apparatus, and the like, and a storage unit storing a control program for executing the process executed in the substrate treating apparatus under the control of the process controller or a program, that is, a treatment recipe, for executing the process in each component according to various data and treatment conditions. Further, the user interface and the storage unit may be connected to the process controller. The treating recipe may be stored in a storage medium in the storage unit, and the storage medium may be a hard disk, and may also be a portable disk, such as a CD-ROM or a DVD, or a semiconductor memory, such as a flash memory.

The controller 30 may control the configurations of the substrate treating apparatus to perform a substrate treating method described below. For example, the controller 30 may control the liquid treating chamber 400, the drying chamber 500, and the transfer chamber 300, which are described below. For example, the controller 30 may be configured to control the configurations of the liquid treating chamber 400, the configurations of the drying chamber 500, and the configurations of the transfer chamber 300.

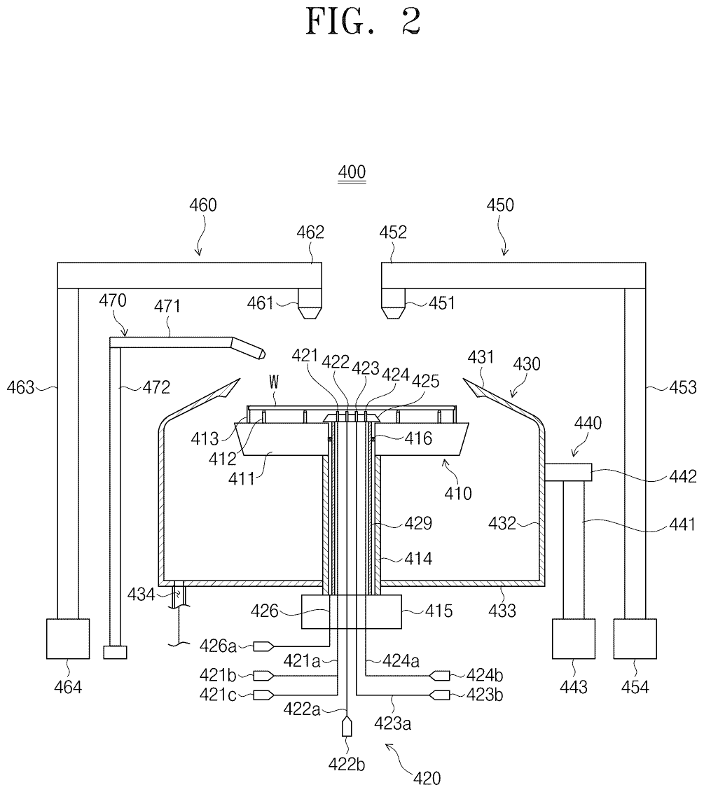

FIG. 2 is a diagram illustrating the liquid treating chamber of FIG. 1.

Referring to FIG. 2, the liquid treating chamber 400 according to the exemplary embodiment of the present invention may treat the substrate W. The liquid treating chamber 400 may treat the substrate W by supplying a treatment solution to the substrate W. The liquid treating chamber 400 may be a single wafer-type treating chamber that treats the substrate W by supplying the treatment solution to a rotating single sheet of the substrate W. The treatment solution supplied by the liquid treating chamber 400 may be a pre-wet liquid, a chemical, and a wet liquid. The treatment solutions supplied by the liquid treating chamber 400 may be cleaning solutions to remove impurities, such as particles, attached to the substrate W.

The liquid treating chamber 400 according to the exemplary embodiment of the present invention may include a support unit 410, a lower supply unit 420, a treating container 430, a lifting unit 440, a first upper supply unit 450, a second upper supply unit 460, and a third supply feed unit 470.

The support unit 410 may support the substrate W. The support unit 410 may be configured to rotate the substrate W. The support unit 410 may support the substrate W in a horizontal position such that a top surface of the substrate W faces in an upper direction and a bottom surface of the substrate W faces in a lower direction.

The support unit 410 may include a rotation plate 411, a support pin 412, a chuck pin 413, a rotation shaft 414, a rotation driver 415, and a bearing 416.

The rotation plate 411 may support and rotate the substrate W. The rotation plate 411 may have a plate shape with a wide top surface and a narrow bottom surface. When viewed from above, a center region of the rotation plate 411 may have an opening formed into which the lower supply unit 420, which will be described later, may be inserted.

The support pin 412 and the chuck pin 413 may be installed on the rotation plate 411.

The support pin 412 may be provided to support the bottom surface of the substrate W. The support pin 412 may be installed with its position fixed. The support pins 412 may be provided in plurality. The support pins 412 may each be configured to support the bottom surface of the substrate W at different locations. The support pins 412 may be installed on the edges of the rotation plate 411, when viewed from above.

The chuck pins 413 may be provided to support the bottom surface and the lateral portion of the substrate W. The chuck pin 413 may be configured to have a stepped shape at ends thereof, such that a stepped horizontal surface of the chuck pin 413 supports the bottom surface of the substrate W and a stepped vertical surface of the chuck pin 413 supports the side surface of the substrate W. The chuck pin 413 may be installed to be movable in position along the lateral direction.

The chuck pins 413 may be provided in plurality. The chuck pins 413 may be installed on the rotation plate 411 from a further outward side than the support pins 412 when viewed from above. When the substrate W is loaded into the liquid treating chamber 400, the chuck pins 413 may be spaced apart in a direction away from the center of the rotation plate 411, and then moved in a direction closer to the center of the rotation plate 411 when the substrate W is placed on the support unit 410 to chuck the substrate W.

The rotating plate 410 may be coupled to the rotation shaft 414. The rotation shaft 414 may be coupled to a lower portion of the rotation plate 411. The rotation shaft 414 may be a hollow shaft. The rotation shaft 414 may be coupled to a lower center region of the rotation plate 411. The rotation shaft 414 may be coupled to the rotation driver 415, which may be a hollow motor. The rotation driver 415 may rotate the rotation shaft 414. The rotation driver 415 may rotate the rotation shaft 414, the rotation shaft 414 may rotate the rotation plate 411, and the rotation plate 411 may rotate the placed substrate W.

The bearing 416 may be provided in the opening formed in the rotation plate 411. The bearing 416 may be provided between a fixed shaft 429 of the lower supply unit 420 described later and the rotation plate 411. The bearing 416 may be installed between the fixed shaft 429 and the rotation plate 411 inserted in the opening formed in the rotation plate 411. The bearing 416 may be a ring-shaped bearing. Even when the rotation plate 411 is rotated by the bearing 416, the lower supply unit 420 including the fixed shaft 429 may not be rotated. The lower supply unit 420 may be independent of the rotation of the rotation plate 411 by the bearing 416.

The lower supply unit 420 may be configured to supply a treatment solution and treatment gas to the bottom surface of the substrate W. The lower supply unit 420 may be configured to supply a pre-wet liquid, a chemical, a wet liquid, and drying gas to the bottom surface of the substrate W.

The pre-wet liquid and the wet liquid supplied by the lower supply unit 420 may be isopropyl alcohol and deionized water. The chemical supplied by the lower supply unit 420 may be selected from a substance containing a sulfuric acid component (for example, SPM containing a sulfuric acid component and a hydrogen peroxide component), a substance containing an ammonia water component (for example, SC-1 (H₂O₂+NH₄OH)), a substance containing a hydrofluoric acid component (for example, diluted hydrogen fluoride (DHF)), a substance containing a phosphoric acid component, and the like. The drying gas supplied by the lower supply unit 420 may be inert gas, for example, nitrogen gas.

In addition, the lower supply unit 420 may supply purge gas into the space between the fixed shaft 429 and the rotation plate 411, and the space between the cap 425 and the rotation plate 411, which will be described later. The purge gas may be inert gas. For example, the purge gas may be nitrogen gas.

The lower supply unit 420 may include a first lower liquid supply nozzle 421, a second lower liquid supply nozzle 422, a third lower liquid supply nozzle 423, a lower gas supply nozzle 424, a cap 425, a fixed shaft 429, and lines and supply sources for supplying the treatment solution and gas.

The cap 425 may be disposed above the top surface of the rotation plate 411. The cap 425 may be positioned to be spaced apart from the top surface of the rotation plate 411. The cap 425 may be configured to cover the opening formed in a center region of the rotation plate 411, when viewed from above. The cap 425 may be coupled with the fixed shaft 429.

The fixed shaft 429 may be a hollow shaft having an empty interior and a hollow shape. The fixed shaft 429 may be installed to be inserted into the rotation shaft 414. The fixed shaft 4290 may be installed to be inserted into the opening formed in the rotation plate 411. The fixed shaft 429 may be configured to have a smaller diameter than the rotation shaft 414 and the opening formed in the rotation plate 411. The fixed shaft 419 may be installed to be spaced apart from the rotation shaft 414 and the rotation plate 411. Since the bearing 416 is installed between the fixed shaft 419 and the rotation shaft 414, the fixed shaft 419 may be provided independently of the rotation of the rotation shaft 414 and the rotation plate 411. Since the fixed shaft 419 is independent of the rotation of the rotation shaft 414 and the rotation plate 411, the cap 425 coupled with the fixed shaft 419 may also be provided independently of rotation of the rotation shaft 414 and the rotation plate 411.

The first lower liquid supply nozzle 421, the second lower liquid supply nozzle 422, the third lower liquid supply nozzle 423, and the lower gas supply nozzle 424 may be installed on the cap 425. The first lower liquid supply nozzle 421, the second lower liquid supply nozzle 422, the third lower liquid supply nozzle 423, and the lower gas supply nozzle 424 may be configured to supply pre-wet liquid, wet liquid, and dry gas to the bottom surface of the substrate W.

A discharge end of the first lower liquid supply nozzle 421 may face the bottom surface of the substrate W. The first lower liquid supply nozzle 421 may supply a pre-wet liquid or a wet liquid. For example, the first lower liquid supply nozzle 421 may supply an organic solvent. The first lower liquid supply nozzle 421 may supply isopropyl alcohol. The first lower liquid supply nozzle 421 may supply isopropyl alcohol that has been heated to a temperature above room temperature, for example, a temperature of 30° C. to 80° C. The first lower liquid supply nozzle 421 may also supply isopropyl alcohol having a temperature of room temperature, for example, a temperature of 10° C. to 25° C.

The first lower liquid supply nozzle 421 may be connected to the first lower fluid supply line 421a. At least a portion of the first lower liquid supply line 421a may be located on the interior of the fixed shaft 429. The first lower liquid supply line 421a may be connected to a first lower high-temperature liquid supply source 421b and a first lower low-temperature liquid supply source 421c. The first lower high-temperature liquid supply source 421a may heat isopropyl alcohol to a temperature of 30° C. to 80° C. and supply the heated isopropyl alcohol to the first lower liquid supply nozzle 421. The first lower low-temperature liquid supply source 421c may supply isopropyl alcohol at room temperature (for example, 10° C. to 25° C.) to the first lower liquid supply nozzle 421.

The second lower liquid supply nozzle 422 may supply pre-wet liquid or wet liquid. For example, the first lower liquid supply nozzle 421 may supply deionized water. The first lower liquid supply nozzle 421 may supply deionized water having a temperature of room temperature, for example, a temperature of 10° C. to 25° C.

The second lower liquid supply nozzle 422 may be connected to the second lower liquid supply line 422a. At least a portion of the second lower liquid supply line 422a may be located on the interior of the fixed shaft 429. The second lower liquid supply line 422a may be connected to the second lower liquid supply source 422b. The second lower liquid supply source 422b may supply deionized water at room temperature (for example, 10° C. to 25° C.) to the first lower liquid supply nozzle 421.

The third lower liquid supply nozzle 423 may supply a chemical that cleans the substrate W. For example, the third lower liquid supply nozzle 423 may supply a chemical selected from a substance containing a sulfuric acid component (for example, SPM containing a sulfuric acid component and a hydrogen peroxide component), a substance containing an ammonia water component (for example, SC-1 (H₂O₂+NH₄OH), a substance containing a hydrofluoric acid component (for example, diluted hydrogen fluoride (DHF)), a substance containing a phosphoric acid component, and the like. The third lower liquid supply nozzle 423 may supply a chemical having a temperature of room temperature, for example, 10° C. to 25° C.

The third lower liquid supply nozzle 423 may be connected to the third lower liquid supply line 423a. At least a portion of the third lower liquid supply line 423a may be located on the interior of the fixed shaft 429. The third lower liquid supply line 423a may be connected to the third lower liquid supply source 423b. The third lower liquid supply source 423b may supply a chemical at room temperature (for example, 10° C. to 25° C.) to the third lower liquid supply nozzle 423.

The lower gas supply nozzle 424 may supply drying gas. For example, the lower gas supply nozzle 424 may supply inert gas, such as drying gas.

The lower gas supply nozzle 424 may be connected to the lower gas supply line 424a. At least a portion of the lower gas supply line 424a may be located on the interior of the fixed shaft 429. The lower gas supply line 424a may be connected to the lower gas supply source 424b. The lower gas supply source 424b may supply inert gas, for example, nitrogen, to the lower gas supply nozzle 424.

The purge gas supply line 426 may supply purge gas into the space between the fixed shaft 429 and the rotation shaft 414. As described above, the fixed shaft 429 and the cap 425 are provided independently with respect to the rotation of the rotation shaft 414 and the rotation plate 411. To this end, the fixed shaft 429 needs to be provided to be spaced apart from the rotation plate 411 and the rotation shaft 414, and the cap 425 needs to be provided to be spaced apart from the rotation plate 411.

In this case, the treatment solutions supplied in the process of treating the substrate W may enter the space between the cap 425 and the rotation plate 411, the space between the fixed shaft 429 and the rotation plate 411, and the space between the fixed shaft 429 and the rotation shaft 414.

To prevent this, the purge gas supply line 426 supplies purge gas to the space between the fixed shaft 429 and the rotation shaft 414 at all times while the substrate treating apparatus is being driven. The purge gas forms an airflow that flows from the space between the fixed shaft 429 and the rotation shaft 414 and into the space between the cap 425 and the rotation plate 411. This airflow may prevent the treatment solutions supplied in the process of treating the substrate W from entering the space between the cap 425 and the rotation plate 411, the space between the fixed shaft 429 and the rotation plate 411, and the space between the fixed shaft 429 and the rotation shaft 414.

The treating container 430 may provide a treating space. The treating container 430 may have a cylindrical shape with an open top. The treating container 430 may also be referred to as a bin, or a cup, or the like. The treating container 430 may be configured to collect the treatment solutions supplied by the lower supply unit 420 and the first, second, and third upper supply units 450, 460, and 470 which will be described later. The support unit 410 may support and rotate the substrate W in the treating space provided by the treating container 430.

The treating container 430 may include an upper portion 431, a lateral portion 432, and a lower portion 433. The lower portion 433 may have a substantially flat disk shape. The lateral portion 432 may be formed by extending upwardly from the outer circumference of the lower portion 433. The upper portion 431 may be formed by extending while upwardly sloping from the lateral portion 432 in a direction toward the center of the support unit 410. The lower portion 433 may be formed with a collection hole 434 for collecting the treatment solution.

In FIG. 2, the present invention has been described based on the case where the treating container 430 has a single cup shape as an example, but the present invention is not limited thereto. For example, the treating container 430 may have a multiple cup shape, such as an inner cup and an outer cup provided on the outer side of the inner cup, in which case the treatment solution may be collected through different collection holes depending on the type of treatment solution to be collected.

The lifting unit 440 may lift the treating container 430. The lifting unit 440 may include a lifting shaft 441, a fixing bracket 442, and a lifting driver 443. The lifting shaft 441 may be coupled with the fixing bracket 442, and the fixing bracket 442 may be coupled with the treating container 430. The lifting shaft 441 may be configured to be movable in an up-and-down direction by the lifting driver 443, which may be a pneumatic/hydraulic cylinder or a motor. The up-and-down movement of the lifting shaft 441 allows the treating container 430 to be lifted.

The first upper supply unit 450 may supply a pre-wet liquid or a wet liquid to the substrate W supported on the support unit 410. The first upper supply unit 450 may supply an organic solvent, for example, isopropyl alcohol, to the substrate W.

The first upper supply unit 450 may include a first upper nozzle 451, a first arm 452, a first movement shaft 453, and a first rotation device 454. The first upper nozzle 451 may be coupled to the first arm 452. The first arm 452 may be coupled to the first movement shaft 453 having a rotational axis in a direction perpendicular to the ground. The first rotation device 454 may rotate the first movement shaft 453. The first rotation device 454 may be a motor. The first upper nozzle 451 may change its position between the standby position and the process position by rotation of the first arm 452.

The standby position may refer to a position where the first upper nozzle 451 gets out of the substrate W when viewed from above, and the process position may refer to a position where the first upper nozzle 451 overlaps the substrate W when viewed from above, for example, a position where the first upper nozzle 451 is aligned with the center of the substrate W.

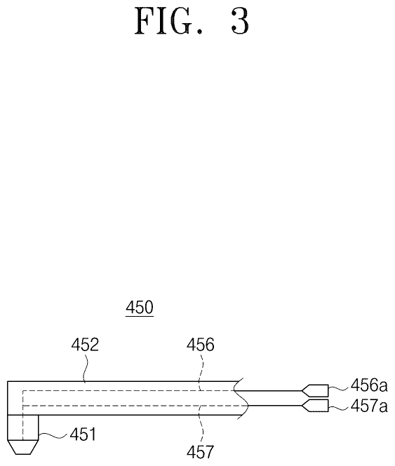

FIG. 3 is a diagram illustrating lines supplying the pre-wet liquid to the first upper nozzle of FIG. 2.

Referring to FIG. 3, the first upper nozzle 451 of the present invention may supply isopropyl alcohol to the substrate W. The first upper nozzle 451 may supply isopropyl alcohol that has been heated to a temperature above room temperature, for example, a temperature of 30° C. to 80° C. The first upper nozzle 451 may supply isopropyl alcohol having a temperature of room temperature, for example, 10° C. to 25° C.

The first nozzle 451 may be connected to a first upper high-temperature liquid supply line 456 and a first upper low-temperature liquid supply line 457. At least a portion of the first upper high-temperature liquid supply line 456 and at least a portion of the first upper low-temperature liquid supply line 457 may be located within the first arm 452. The first upper high-temperature liquid supply line 456 may be connected to a first upper high-temperature liquid supply source 456a. The first upper high-temperature liquid supply source 456a may supply isopropyl alcohol heated to a temperature above room temperature, for example, a temperature of 30° C. to 80° C., to the first upper nozzle 451. The first upper low-temperature liquid supply line 457 may be connected to a first upper low-temperature liquid supply source 457a. The first upper low-temperature liquid supply source 457a may supply isopropyl alcohol having a temperature of room temperature, for example, 10° C. to 25° C., to the first upper nozzle 451. This configuration allows both high-temperature isopropyl alcohol and low-temperature isopropyl alcohol to be discharged from the single first upper nozzle 451. This has the advantage of minimizing the time required to treat the substrate W, as no repositioning of the nozzles is required to change from a first pre-wet operation S10 to a second pre-wet operation S20, which will be described later.

Referring again to FIG. 2, the second upper supply unit 460 may supply a chemical to the substrate W supported on the support unit 410. The second upper supply unit 460 may supply the substrate W with a chemical selected from a substance containing a sulfuric acid component (for example, SPM containing a sulfuric acid component and a hydrogen peroxide component), a substance containing an ammonia water component (for example, SC-1 (H₂O₂+NH₄OH)), a substance containing a hydrofluoric acid component (for example, diluted hydrogen fluoride (DHF)), a substance containing a phosphoric acid component, and the like. The second upper supply unit 460 may supply a chemical having a temperature of room temperature, for example, 10° C. to 25° C.

The second upper supply unit 460 may include a second upper nozzle 461, a second arm 462, a second movement shaft 463, and a second rotation device 464. The second upper nozzle 461, the second arm 462, the second movement shaft 463, and the second rotation device 464 have the same or similar structure/function as the first upper nozzle 451, the first arm 452, the first movement shaft 453, and the first rotation device 454 described above, and therefore redundant description will be omitted.

The third upper supply unit 470 may include a third upper nozzle 471 and a fixing bar 472. The third upper nozzle 471 may supply a pre-wet liquid or a wet liquid to the substrate W supported on the support unit 410. The third upper nozzle 471 may supply deionized water to the substrate W. The third upper nozzle 471 may supply deionized water having a temperature of room temperature, for example, 10° C. to 25° C., to the substrate W.

The third upper nozzle 471 may be fixed in position. The fixing bar 472 may fix the position of the third upper nozzle 471. A discharge end of the third upper nozzle 471 may be configured to face the center region of the substrate W. The deionized water discharged by the third upper nozzle 471 may need to be supplied from time to time as needed during the liquid treatment operation S10, so that the third upper nozzle 471 may be configured to discharge deionized water into the center region of the substrate W at any time, unlike the first and second upper nozzles 451 and 461.

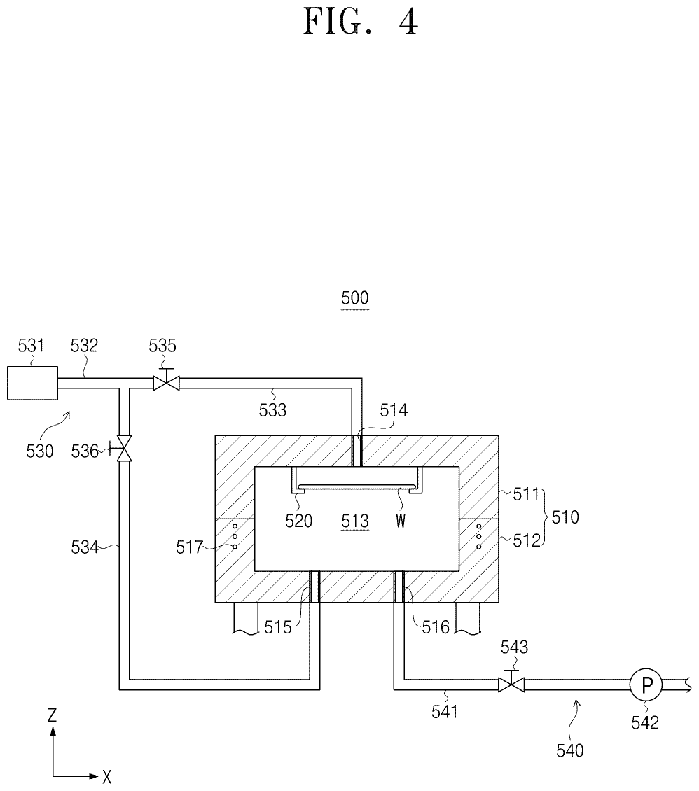

FIG. 4 is a diagram illustrating the drying chamber of FIG. 1.

Referring to FIG. 4, the drying chamber 500 according to the exemplary embodiment of the present invention may include a body 510, a support member 520, a fluid supply unit 530, and a fluid exhaust unit 540.

The body 510 may provide a treating space 513 where the substrate W is treated. The body 510 may include a first body 511 and a second body 512. At least one of the first body 511 and the second body 512 may have a shape that is recessed in a direction away from the other of the first body 511 and the second body 512. The first body 511 and the second body 512 may be combined with each other to define the treating space 513. The first body 511 and the second body 512 may be formed of a material that may withstand the high pressure conditions of the treating space 513. For example, the first body 511 and the second body 512 may be formed from a material, such as a metal, such as aluminum. The first body 511 may be an upper body positioned at the top, and the second body 512 may be a lower body positioned at the bottom.

A location of at least one of the first body 511 and the second body 512 may be changed by a driver (not illustrated). For example, the position of the first body 511 may be fixed, and the second body 512 may be configured to be movable along the third direction Z. The driver may be any one of an air cylinder, a pneumatic cylinder, a motor, and a magnetic levitation actuator.

The driver may move the second body 512 between an open position and a close position. When the second body 512 is in the open position, the treating space 513 may be open to the outside. When the second body 512 is in the close position, the first body 511 and the second body 512 may be combined with each other to provide the sealed treating space 513.

The first body 511 may be provided with a first supply port 514. The first supply port 514 may be connected to the first fluid supply line 533, which will be described later, to supply treatment fluid to the treating space 513. An outlet of the first supply port 514 faces an upper region of the treating space 513 and may face the upper surface of the substrate W resting on the support member 520. The first supply port 514 may be formed on the first body 511 itself, or may be provided as a separate supply pipe inserted into the first body 511.

The second body 512 may be provided with a second supply port 515. The second supply port 515 may be connected to a second fluid supply line 534, which will be described later, to supply treatment fluid to the treating space 513. The outlet of the second supply port 515 may face a lower region of the treating space 513. Similar to the first supply port 514, the second supply port 515 may be formed in the second body 512 itself, or may be provided as a separate supply pipe inserted into the second body 512.

Additionally, the second body 512 may be provided with an exhaust port 516. The exhaust port 516 may be connected to the exhaust line 541, which will be described later, to exhaust the atmosphere of the treating space 513. The exhaust port 516 may the exhaust treatment fluid, such as carbon dioxide, supplied to the treating space 513 to the outside of the treating space 513 to reduce the pressure in the treating space 513. The exhaust port 516 may be provided in parallel with the second supply port 515. Similar to the first supply port 514 and second supply port 515, the exhaust port 516 may be formed in the second body 512 itself, or may be provided as a separate supply pipe inserted into the second body 512.

In the example described above, the present invention has been described based on the case where the first supply port 514 is provided on the first body 511 and the second supply port 515 and exhaust port 516 are provided on the second body 512 as an example, but the present invention is not limited thereto. For example, the first supply port 514, the second supply port 515, and the exhaust port 516 may all be provided on the first body 511, or all may be provided on the second body 512.

The body 510 may be provided with a heater 517. The heater 517 may be installed while being buried in the interior of the first body 511 and/or the second body 512. The heater 517 may be a resistive heater. Alternatively, the heater 517 may be variously modified to any known device that generates heat. The heater 517 may increase the temperature of the treating space 513. The heater 517 may maintain the temperature of the treating space 513 at a set temperature. Here, the set temperature may be set to a temperature above a critical temperature that allows the state of the treatment fluid to remain supercritical.

The support member 528 may support the substrate W. The support member 520 may be configured to support the substrate W in the treating space 513 provided by the body 510.

The support member 520 may be configured to support a bottom surface of the substrate W. The support member 520 may be configured to support the bottom edge region of the substrate W. The support member 520 may be fixedly installed on the underside of the first body 511. The support members 520 may be provided in pairs. Each support member 520 may extend in a downward direction from the first body 511 toward the second body 512 and may have a laterally bent shape at the end to support the bottom surface of the substrate W.

When the area of contact between the substrate W and the support member 520 is large, the risk of damage, such as scratches, to the bottom surface of the substrate W increases; however, the support member 520 may be configured to support only the edge region of the bottom surface of the substrate W, thereby minimizing the area of contact with the bottom surface of the substrate W.

The fluid supply unit 530 may supply the treatment fluid to the treating space 513. The treatment fluid may be drying gas that removes any residual treatment solution on the substrate W. For example, the treatment fluid may be carbon dioxide gas. The treatment fluid may also be converted to a supercritical state and supplied to the treating space 513. Alternatively, the treatment fluid may be supplied to the treating space 513 in a gaseous state and phase converted to the supercritical state in the treating space 513.

The fluid supply unit 530 may include a fluid supply source 531, a main supply line 532, a first fluid supply line 533, a second fluid supply line 534, a first supply valve 535, and a second supply valve 536.

The supply lines 532, 533, and 534 may be equipped with line heaters (not illustrated) to heat the treatment fluid flowing in the supply lines 532, 533, and 534.

The fluid supply source 531 may store and supply a treatment fluid. The fluid supply source 531 may be a fluid storage tank capable of storing and supplying the treatment fluid. The fluid supply source 531 may be configured to store and supply carbon dioxide.

The fluid supply source 531 may be connected to one end of the main supply line 532. The other end of the main supply line 532 may be branched into a first fluid supply line 533 and a second fluid supply line 534. The first fluid supply line 533 may be connected to the first supply port 514 described above. The second fluid supply line 534 may be connected to the second supply port 515. The first fluid supply line 533 may be configured to supply treatment fluid to an upper region of the treating space 513, and the second fluid supply line 534 may be configured to supply treatment fluid to a lower region of the treating space 513.

The first supply valve 535 may be installed in the first fluid supply line 533. The first supply valve 535 may be provided as an auto valve that receives a control signal from the controller 30 to allow or block the flow of the treatment fluid in the first fluid supply line 533.

Similarly, the second fluid supply line 534 may be provided with the second supply valve 536. The second supply valve 536 may be provided as an auto-valve that receives a control signal from the controller 30 to allow or block the flow of the treatment fluid in the second fluid supply line 534.

The fluid exhaust unit 540 may control the atmosphere of the treating space 513. The fluid exhaust unit 540 may exhaust the treatment fluid supplied to the treating space 513 to the outside of the drying chamber 500. The fluid exhaust unit 540 may include a fluid exhaust line 541, an exhaust device 542, and an exhaust valve 543.

The fluid exhaust line 541 may be connected with the exhaust port 516 described above. The exhaust valve 543 may be installed in the fluid exhaust line 541, and the exhaust valve 543 may be provided as an auto valve that receives a control signal from the controller 30 to allow or block the flow of the treatment fluid in the exhaust line 541.

An exhaust device 542 may be coupled to the exhaust line 541. The exhaust device 542 may be a pressure reducing device that depressurizes the treating space 513. For example, the exhaust device 542 may be a pump. However, without limitation, the exhaust device 542 may be variously modified to any known device that is capable of providing depressurization to the treating space 513 through the exhaust line 541 and the exhaust port 516.

Hereinafter, a substrate treating method according to an exemplary embodiment of the present invention will be described. The controller 30 may control the configurations of the substrate treating apparatus to enable the substrate treating apparatus to perform the substrate treating methods described herein. For example, the controller 30 may control the liquid treating chamber 400, the drying chamber 500, and the transfer chamber 300.

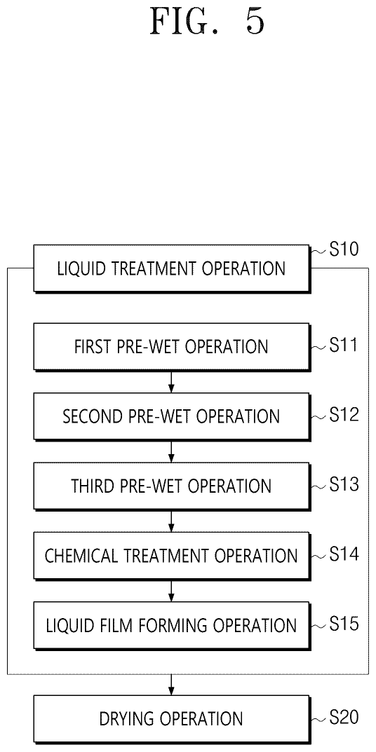

FIG. 5 is a flowchart illustrating a substrate treating method according to an exemplary embodiment of the present invention.

A substrate treatment operation according to an exemplary embodiment of the present invention may include a liquid treatment operation S10, and a drying operation S20. The liquid treatment operation S10 may be performed in the liquid treating chamber 400, and the drying operation S20 may be performed in the drying chamber 500. The substrate W on which the liquid treatment operation S10 has been performed may be loaded into the drying chamber 500 via the transfer chamber 300. A pattern, which may be a microstructure, may be formed on the substrate W that is to be treated. The pattern may have a very high level of high aspect ratio.

The liquid treatment operation S10 may include a first pre-wet operation S11, a second pre-wet operation S12, a third pre-wet operation S13, a chemical treatment operation S14, and a liquid film formation operation S15, which may be performed sequentially.

In the following, a first pre-wet liquid is defined as a treatment solution supplied in the first pre-wet operation S11, a second pre-wet liquid is defined as a treatment solution supplied in the second pre-wet operation S12, a chemical is defined as a treatment solution supplied in the chemical treatment operation S14, and a wet liquid is defined as a treatment solution supplied in the liquid film formation operation (S15).

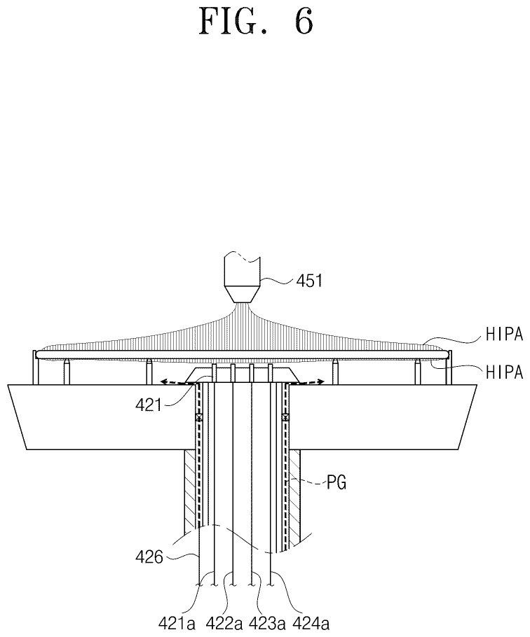

The first pre-wet operation S11 may include supplying the first pre-wet liquid to the top surface and/or the bottom surface of the rotating substrate W (see FIG. 6). In the first pre-wet operation S11, the first upper nozzle 451 and/or the first lower liquid supply nozzle 421 may supply the first pre-wet liquid. The first pre-wet liquid supplied in the first pre-wet operation S11 may be an organic solvent, for example, isopropyl alcohol. The first pre-wet liquid supplied to the first pre-wet operation S11 may be isopropyl alcohol (HIPA) heated to a temperature of 30° C. to 80° C., which is a temperature higher than room temperature. For example, the first pre-wet liquid may be isopropyl alcohol heated to 79° C. and having surface tension of 16 dyn/cm. In addition, in the first pre-wet operation S11, purge gas (PG) may be continuously supplied via the purge gas supply line 426.

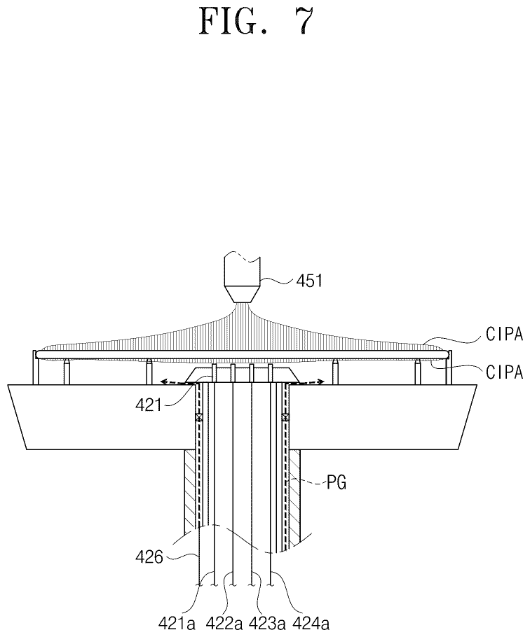

The second pre-wet operation S12 may include supplying the second pre-wet liquid to the top and/or the bottom surface of the rotating substrate W (see FIG. 7). The second pre-wet operation S11 may include supplying the second pre-wet liquid by the first upper nozzle 451 and/or the first lower liquid supply nozzle 421. The second pre-wet liquid supplied in the second pre-wet operation S12 may be an organic solvent, for example, isopropyl alcohol. The second pre-wet liquid supplied in the second pre-wet operation S12 may be isopropyl alcohol (CIPA) having a temperature of 10° C. to 25° C., which is about room temperature. For example, the second pre-wet liquid may be isopropyl alcohol with a temperature of 15° C. and surface tension of 23 dyn/cm. In addition, in the second pre-wet operation S12, purge gas (PG) may be continuously supplied via the purge gas supply line 426.

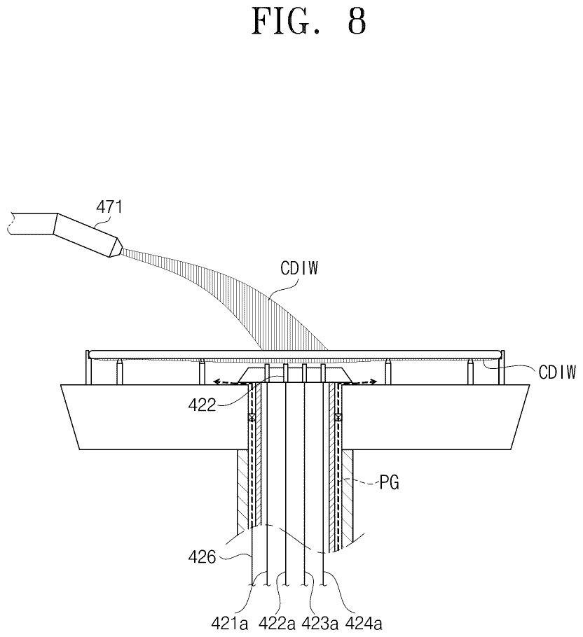

The third pre-wet operation S13 may include supplying the third pre-wet liquid to the top surface and/or the bottom surface of the rotating substrate W (see FIG. 8). The third pre-wet operation S13 may include supplying the third pre-wet liquid by the third upper nozzle 471 and/or the second lower liquid supply nozzle 422. The third pre-wet liquid supplied in the third pre-wet operation S13 may be deionized water. The third pre-wet liquid supplied in the third pre-wet operation S13 may be deionized water (CDIW) having a temperature of 10° C. to 25° C., which is about room temperature, and having surface tension of 72 dyn/cm. In addition, in the third pre-wet operation S13, purge gas (PG) may be continuously supplied via the purge gas supply line 426.

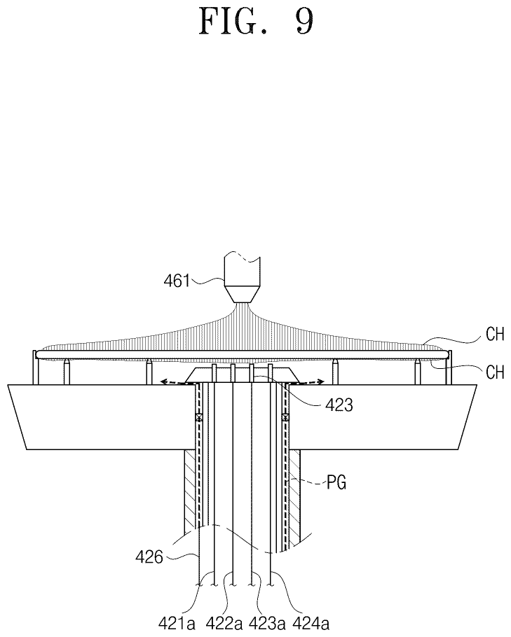

The chemical treatment operation S14 may include supplying a chemical to the top surface and/or the bottom surface of the rotating substrate W (see FIG. 9). The chemical treatment operation S14 may include supplying a chemical CH by the second top nozzle 461 and/or the third lower liquid supply nozzle 423. The chemical supplied in the chemical treatment operation S14 may be selected from a substance containing a sulfuric acid component (for example, SPM containing a sulfuric acid component and a hydrogen peroxide component), a substance containing an ammonia water component (for example, SC-1 (H₂O₂+NH₄OH)), a substance containing a hydrofluoric acid component (for example, diluted hydrogen fluoride (DHF)), a substance containing a phosphoric acid component, and the like. The chemical supplied in the chemical treatment operation S14 may be a chemical having a temperature of 10° C. to 25° C., which is a temperature about room temperature. In addition, in the chemical treatment operation 514, purge gas (PG) may be continuously supplied via the purge gas supply line 426.

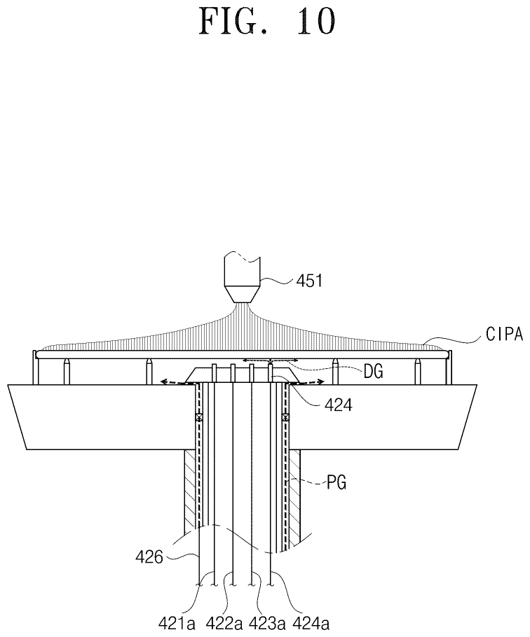

In the liquid film formation operation 515, the wet liquid may be supplied to the top surface of the rotating substrate W and dry gas DG may be supplied to the bottom surface of the substrate W (see FIG. 10). The wet liquid supplied to the top surface of the substrate W in the liquid film formation operation S15 may be an organic solvent, for example, isopropyl alcohol at room temperature. The dry gas DG supplied to the bottom surface of the substrate W in the liquid film formation operation S15 may be inert gas, for example, nitrogen gas. The wet liquid may be supplied by the first upper nozzle 451. The drying gas DG may be supplied by the lower gas supply nozzle 424. In the liquid film formation operation S15, the wet liquid is supplied to the top surface of the substrate W to form a liquid film, and the bottom surface of the substrate W may be dried.

The substrate having the top surface on which the liquid film has been formed and the dried bottom surface may be unloaded from the liquid treating chamber 400 and loaded into the drying chamber 500 via the transfer chamber 300. The transferring the substrate W with the liquid film formed is to prevent the substrate W from being dried naturally and causing defects, such as water marks, on the substrate W.

In the drying operation S20, the substrate having the top surface on which the liquid film has been formed and the dried bottom surface is placed on the support member 520, and the fluid supply unit 530 supplies treatment fluid SG, for example, carbon dioxide as a supercritical fluid, to the treating space 513 to remove the liquid film remaining on the substrate W, so that the substrate W may be dried.

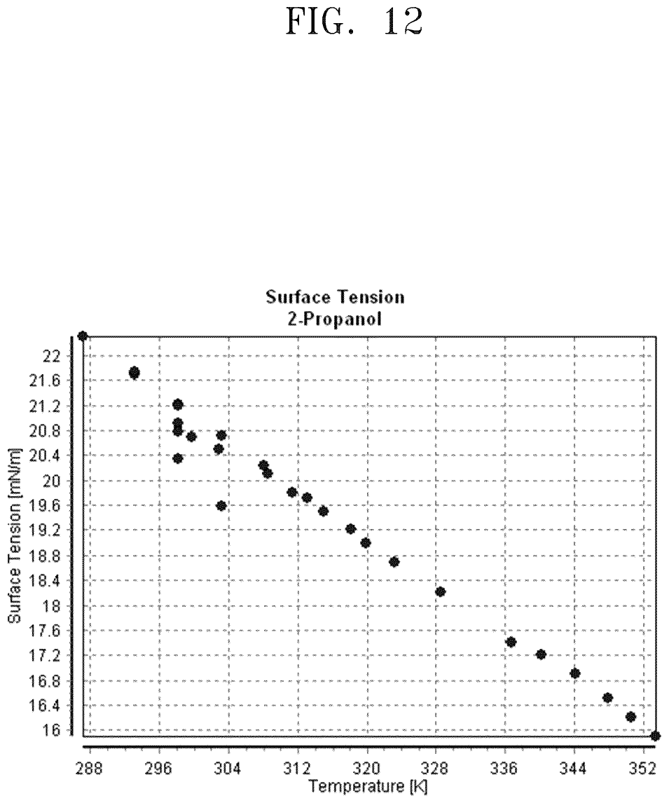

FIG. 12 is a graph illustrating a change in surface tension of the pre-wet liquid according to a change in temperature.

Referring now to FIG. 12, FIG. 12 is a graph illustrating the change in surface tension according to temperature of isopropyl alcohol, which may be supplied as a pre-wet liquid in the first pre-wet operation S10 and the second pre-wet operation S20. As illustrated in FIG. 12, it may be seen that as the temperature of the isopropyl alcohol increases, the surface tension decreases.

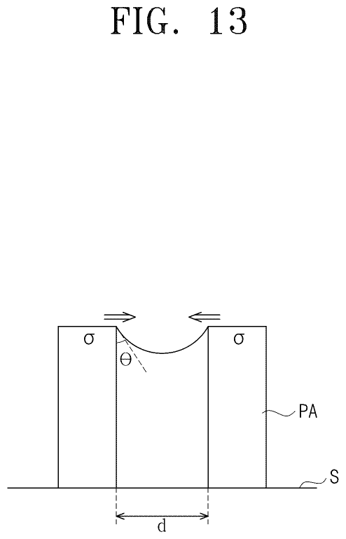

FIG. 13 is an illustrative diagram for illustrating a change in capillary force according to surface tension of the pre-wet liquid.

The substrate W which is to be treated in the present invention has microstructured patterns PA formed on the surface of silicon S. When a treatment solution, such as a pre-wet liquid, is penetrated between the PAs, capillary force a is exerted on the PAs by the surface tension of the pre-wet liquid. The capillary force a acts in the direction in which the patterns PAs are closer together. When the capillary force a increases, the collapse phenomenon of the patterns PAs may easily occur.

The capillary force a has the following formula.

$$σ = 2 γcosθ / d$$

σ is the capillary force, γ is the surface tension of the treatment solution penetrated between the PAs, θ is the contact angle between the patterns PAs and the treatment solution, and d may be the interval between the patterns PAs.

In recent years, the interval d between the patterns PAs has become very small as the structure of the patterns PAs has become very fine. In addition, the linewidth of the patterns PAs has also become very small, so that even a small increase in the surface tension of the treatment solution may easily cause the pattern collapse phenomenon due to capillary force a.

Furthermore, when the amount of treatment solution penetrating between the patterns PAs is different, the capillary forces a generated by different regions of the substrate W may be different. When the capillary force a generated in different regions of the substrate W is different, pattern collapse phenomenon may occur due to an imbalance of forces. That is, when the treatment solution is not adequately penetrated between the patterns PAs, pattern collapse phenomenon may occur more easily due to an imbalance of capillary forces a generated in different regions of the substrate W.

According to the exemplary embodiment of the present invention, the first pre-wet operation S11, which is performed first on the substrate W in the liquid treatment operation S10, uses isopropyl alcohol with low surface tension as the first pre-wet liquid. In particular, isopropyl alcohol heated to a temperature higher than room temperature is used as the first pre-wet liquid.

Isopropyl alcohol heated to a temperature higher than room temperature has very low surface tension. The surface tension of isopropyl alcohol at 79° C. is about 16 dynes/cm, which is about 72% of the surface tension of isopropyl alcohol at room temperature of 22 dynes/cm. Therefore, when heated isopropyl alcohol with low surface tension is used as the first pre-wet liquid, the pattern collapse phenomenon caused by the first pre-wet liquid may be minimized. Furthermore, since the heated isopropyl alcohol has very low surface tension, the isopropyl alcohol has excellent penetrating force between the patterns PAs, and thus may penetrate relatively uniformly between the patterns PAs formed on the substrate W. This minimizes the occurrence of the pattern collapse phenomenon due to an imbalance of capillary forces in different areas of the substrate W.

Furthermore, according to the exemplary embodiment of the invention, after supplying isopropyl alcohol heated to a temperature higher than room temperature, the second pre-wet operation S12 is performed in which room temperature isopropyl alcohol is supplied.

Isopropyl alcohol has high volatility by nature, and heated isopropyl alcohol has even higher volatility. Therefore, the heated isopropyl alcohol supplied in the first pre-wet operation S11 may evaporate rapidly from the substrate W. In particular, this evaporation may be more pronounced at the edge regions of the substrate W. In this case, the wettability of the substrate W is not adequate because the wettability of the substrate W may vary from region to region of the substrate W.

Therefore, in the exemplary embodiment of the present invention, the second pre-wet operation S12 is performed immediately after the first pre-wet operation S11. In other words, in the exemplary embodiment of the present invention, when the high-temperature isopropyl alcohol penetrates between the patterns formed on the substrate W, the space between the patterns is filled with the high-temperature isopropyl alcohol, and then room-temperature isopropyl alcohol is supplied over the high-temperature isopropyl alcohol. Since the space between the patterns is already filled with high-temperature isopropyl alcohol with low surface tension, it is possible to prevent the above-described pattern collapse phenomenon from occurring, and since room-temperature isopropyl alcohol is supplied over the high-temperature isopropyl alcohol, it is possible to prevent the evaporation phenomenon of isopropyl alcohol.

Furthermore, since the nozzle supplying the first pre-wet liquid and the nozzle supplying the second pre-wet liquid are both the same first upper nozzle 451, the switch from the first pre-wet operation S11 to the second pre-wet operation S12 may be performed without interruption. In other words, the first pre-wet operation S11 and the second pre-wet operation S12 may be performed continuously. As the first pre-wet operation S11 and the second pre-wet operation S12 are performed continuously, it becomes possible to supply room temperature isopropyl alcohol in the second pre-wet operation S12 before the high temperature isopropyl alcohol supplied in the first pre-wet operation S11 is evaporated.

Furthermore, in the exemplary embodiment of the present invention, after the second pre-wet operation S12, the third pre-wet operation S13 is further performed. In the third pre-wet operation S13, deionized water may be supplied to the substrate W. This is to increase the efficiency of cleaning the substrate W in the chemical treatment operation S14 performed later. When the chemicals supplied in the chemical treatment operation S14 are chemicals containing water, such as an aqueous solution, deionized water may be supplied to the substrate W in advance in the third pre-wet operation S13 to further increase the efficiency of cleaning the substrate W in the chemical treatment operation S14.

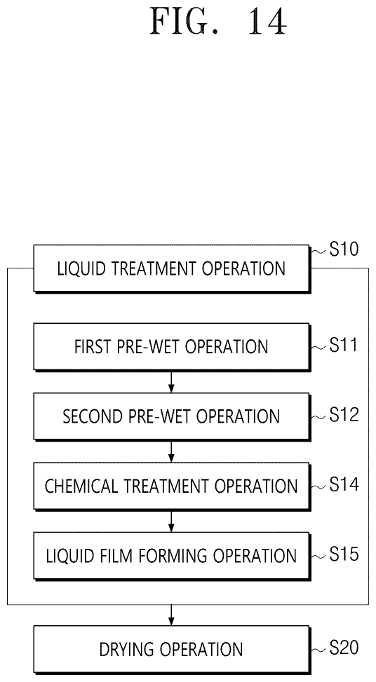

However, the present invention is not limited thereto, and the third pre-wet operation S13 may be omitted, as illustrated in FIG. 14. Also, as needed, the second pre-wet operation S12 rather than the third pre-wet operation S13 may be omitted. Even when the second pre-wet operation S12 is omitted instead of the third pre-wet operation S13, the effect of minimizing the pattern collapse phenomenon described above may be the same or similar, since the high-temperature isopropyl alcohol is supplied and then deionized water at room temperature is supplied.

In the example described above, the present invention has been described based on the case where the first pre-wet operation S11 includes supplying the first pre-wet liquid heated to a temperature higher than room temperature, and the second pre-wet operation S12 and the third pre-wet operation S13 include supplying the second pre-wet liquid at room temperature and supplying the third pre-wet liquid at room temperature as an example, but the present invention is not limited thereto.

When the first pre-wet liquid heated to a temperature above room temperature is supplied, the substrate W may be heated to a relatively high temperature. When the second pre-wet liquid or the third pre-wet liquid at room temperature with a large temperature difference from the first pre-wet liquid is supplied, warping may occur due to a sudden change in temperature of the substrate W.

Therefore, in another exemplary embodiment of the present invention, the substrate W may be treated by supplying the first pre-wet liquid heated to a temperature higher than room temperature and supplying a chemical at room temperature, but by controlling the temperature of the second pre-wet liquid or the third pre-wet liquid to a temperature lower than the first pre-wet liquid and a temperature higher than room temperature (for example, a temperature higher than the chemical), it is possible to suppress the warping phenomenon caused by the sudden temperature change described above.

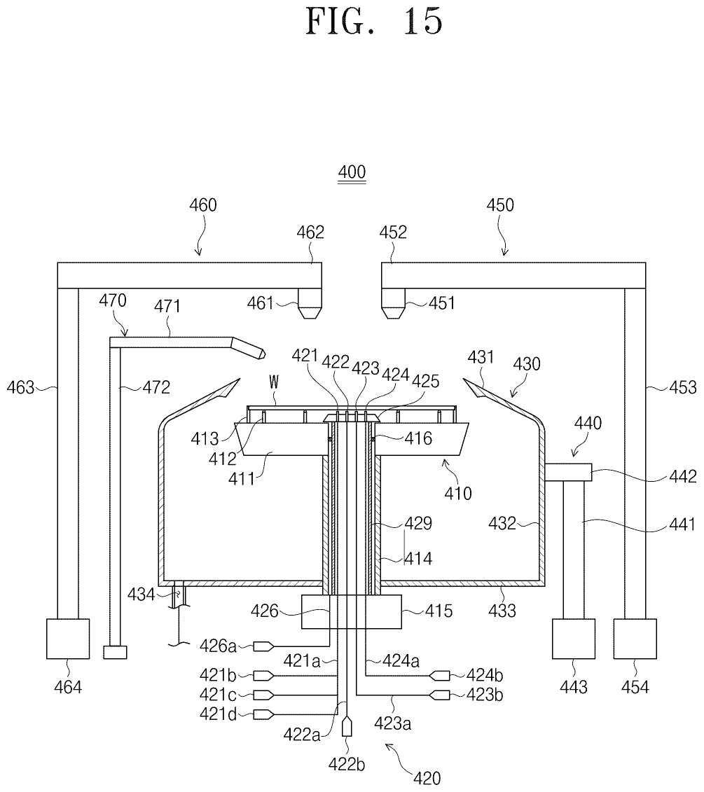

To this end, a first lower medium-temperature liquid supply source 421d may be further installed in the first lower liquid supply line 421a, as illustrated in FIG. 15. The first lower medium-temperature liquid supply source 421d may be configured to supply medium-temperature pre-wet liquid, or medium-temperature wet liquid. The first lower medium-temperature liquid supply source 421d may be configured to supply isopropyl alcohol at a temperature lower than the first lower high-temperature liquid supply source 421b and higher than the first lower low-temperature liquid supply source 421c.

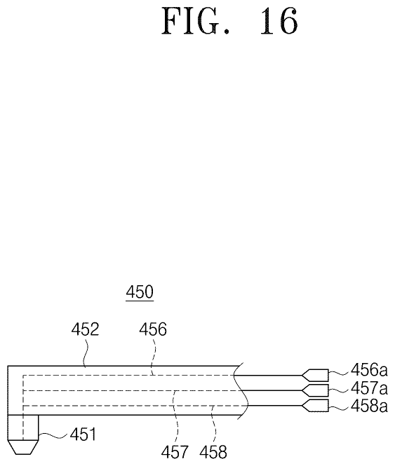

Further, as illustrated in FIG. 16, the first upper nozzle 451 may be further connected to a first upper medium-temperature liquid supply line 458 and a first upper medium-temperature liquid supply source 458a. The first upper medium-temperature liquid supply source 458a may be configured to supply medium-temperature pre-wet liquid or medium-temperature wet liquid. The first upper medium-temperature liquid supply source 458a may be configured to supply isopropyl alcohol at a temperature lower than the first upper high-temperature liquid supply source 456a and higher than the first upper low-temperature liquid supply source 457a.

In some cases, it is also contemplated to reduce the temperature of the substrate W from high temperature to medium temperature without the addition of the first lower medium-temperature liquid supply source 421d, the first upper medium-temperature liquid supply line 458, and the first upper medium-temperature liquid supply source 458a described above.

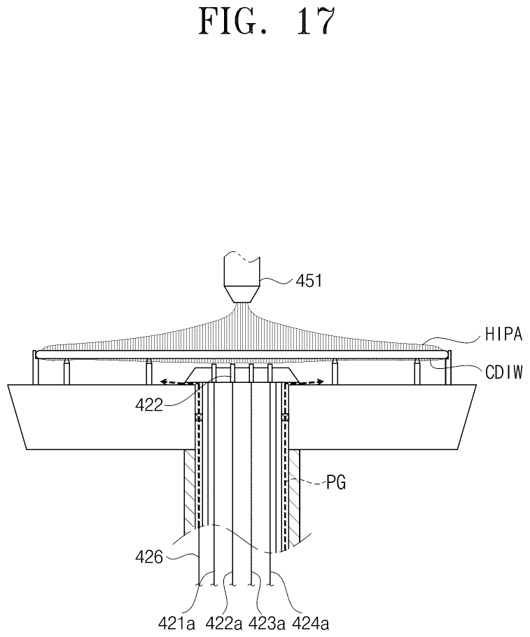

For example, as illustrated in FIG. 17, in the first pre-wet operation S11, high-temperature isopropyl alcohol is supplied to the top surface of the substrate W and high-temperature isopropyl alcohol is supplied to the bottom surface, and in the second pre-wet operation S12 or the third pre-wet operation S13, a high temperature isopropyl alcohol, which is the same temperature as the first pre-wet operation S11, is supplied to the top surface of the substrate W, and deionized water, which is a low temperature pre-wet liquid, is supplied to the bottom surface of the substrate W.

The high-temperature isopropyl alcohol supplied to the top surface of the substrate W has low surface tension, so the high-temperature isopropyl alcohol penetrates directly into the space between the patterns formed on the top surface of the substrate W, and the low-temperature deionized water supplied to the bottom surface of the substrate W reduces the temperature of the substrate W, which indirectly reduces the temperature of the high-temperature isopropyl alcohol supplied to the top surface of the substrate W.

In this case, the high-temperature isopropyl alcohol supplied directly to the top surface of the substrate W is indirectly lowered in temperature by the low-temperature deionized water supplied to the bottom surface of the substrate W after penetrating into the space between the patterns formed on the top surface of the substrate W, so that the advantage of the excellent penetrating power of the isopropyl alcohol is obtained, and the phenomenon of evaporation of the high-temperature isopropyl alcohol is prevented. In addition, by changing the temperature of the substrate W to a medium temperature, the occurrence of warping phenomena of the substrate W due to the later supply of room temperature chemicals may be minimized. It is also advantageous that the change from the first pre-wet operation S11 to the second pre-wet operation S12 or third pre-wet operation S13 may be performed continuously by changing only the pre-wet liquid supplied to the bottom surface of the substrate W, while maintaining the supply of high-temperature isopropyl alcohol to the top surface of the substrate W.

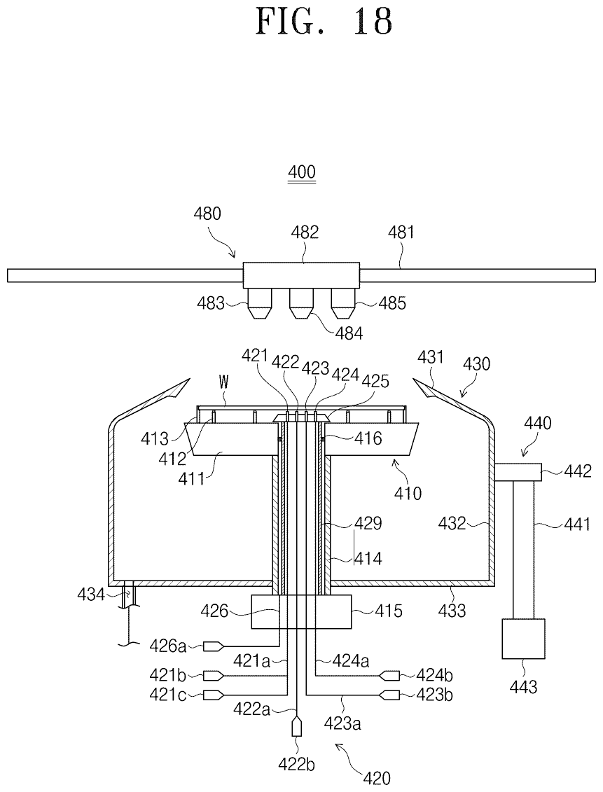

In the examples described above, the present invention has been described based on the case where the first upper nozzle 451, the second upper nozzle 461, and the third upper nozzle 471 are all coupled to separate arms 452 and 462, or the fixing bar 472 as an example, but the present invention is not limited thereto. For example, as illustrated in FIG. 18, the liquid treating chamber 400 may include an upper liquid supply unit 480, and the upper liquid supply unit 480 may include a first upper nozzle 483, a second upper nozzle 484, and a third upper nozzle 485. The first upper nozzle 483, the second upper nozzle 484, and the third upper nozzle 485 may perform the same or similar functions as the first upper nozzle 451, the second upper nozzle 461, and the third upper nozzle 471 described above.

Further, the upper liquid supply unit 480 includes a guide rail 481 extending in a horizontal direction and installed on a top side of the support unit 410 and a moving body 482 coupled to the guide rail 481 and configured to be laterally movable, and the first upper nozzle 483, the second upper nozzle 484, and the third upper nozzle 485 may all be provided while being coupled to the moving body 482.

In the example described above, the present invention has been described based on the case where the pre-wet liquid and the chemical are supplied to the top surface and the bottom surface of the substrate W in the first pre-wet operation S11, the second pre-wet operation S12, and the chemical treatment operation S13, as an example, but is not limited thereto. For example, in the first pre-wet operation S11, the second pre-wet operation S12, and the chemical treatment operation S13, the pre-wet liquid and chemicals may be supplied to the top surface of the substrate W only.

In the example described above, the present invention has been described based on the case where the same type of pre-wet liquid or chemical is supplied to the top surface and the bottom surface of the substrate W in the first pre-wet operation S11, the second pre-wet operation S12, and the chemical treatment operation S13, as an example, but is not limited thereto. For example, in the first pre-wet operation S11, the second pre-wet operation S12, and the chemical treatment operation S13, different types of pre-wet liquids and chemicals may be supplied to the top surface and the bottom surface of the substrate W. For example, in the first pre-wet operation S11, the first pre-wet liquid, which is high temperature isopropyl alcohol, may be supplied to the top surface of the substrate W, and the first pre-wet liquid, which is high temperature deionized water, may be supplied to the bottom surface of the substrate W.

In the example described above, the present invention has been described based on the case where the first upper nozzle 451 is configured to provide both high-temperature isopropyl alcohol and low-temperature isopropyl alcohol as an example, but is not limited thereto. For example, the first upper supply unit 450 may have a first nozzle for supplying high-temperature isopropyl alcohol and a second nozzle for supplying low-temperature isopropyl alcohol. In this case, the first pre-wet operation S11 in which the first nozzle supplies high-temperature isopropyl alcohol and the second pre-wet operation S12 in which the second nozzle supplies low-temperature isopropyl alcohol may partially overlap in order to provide an uninterrupted transition from the first pre-wet operation S11 to the second pre-wet operation S12. During the overlap, the first nozzle may move in a direction away from the center of the substrate W, and the second nozzle may move in a direction from the periphery of the substrate W toward the center of the substrate W.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even if not specifically illustrated or described. The modifications are not to be considered as departing from the spirit and scope of the present invention, and all such modifications that would be obvious to one of ordinary skill in the art are intended to be included within the scope of the accompanying claims.

1. A method of treating a substrate, the method comprising:
a first pre-wet operation of supplying a first pre-wet liquid to a rotating substrate;
a second pre-wet operation of supplying a second pre-wet liquid having a temperature different from the first pre-wet liquid to the rotating substrate, the second pre-wet operation being performed after the first pre-wet operation; and
a chemical treatment operation of supplying a chemical that is a liquid of a different type from the first pre-wet liquid and the second pre-wet liquid to the rotating substrate, the chemical treatment operation being performed after the second pre-wet operation.

2. The method of claim 1, wherein the temperature of the first pre-wet liquid is higher than the temperature of the second pre-wet liquid.

3. The method of claim 2, wherein the first pre-wet liquid is an organic solvent provided with a temperature higher than room temperature.

4. The method of claim 3, wherein the first pre-wet liquid is an isopropyl alcohol provided with a temperature higher than room temperature.

5. The method of claim 4, wherein the first pre-wet liquid is isopropyl alcohol provided at a temperature of 30° C. to 80° C.

6. The method of claim 1, wherein the second pre-wet liquid is isopropyl alcohol or deionized water.

7. The method of claim 1, wherein the second pre-wet liquid is provided with a temperature of from 10° C. to 25° C.

8. The method of claim 1, wherein the temperature of the second pre-wet liquid is lower than the temperature of the first pre-wet liquid and is higher than the temperature of the chemical.

9. The method of claim 1, further comprising:
a third pre-wet operation of supplying a third pre-wet liquid different from the second pre-wet liquid to the rotating substrate, the third pre-wet operation being performed between the second pre-wet operation and the chemical treatment operation.

10. The method of claim 9, wherein the second pre-wet liquid is isopropyl alcohol, and
the third pre-wet liquid is deionized water.

11. The method of claim 10, wherein a temperature of the third pre-wet liquid is closer to the temperature of the second pre-wet liquid than the temperature of the first pre-wet liquid.

12. The method of claim 1, wherein the temperature of the second pre-wet liquid supplied in the second pre-wet operation is higher than the temperature of the chemical and is lower than the temperature of the first pre-wet liquid.

13. The method of claim 1, wherein the second pre-wet operation includes supplying the second pre-wet liquid at a first temperature to a top surface of the rotating substrate, and supplying the second pre-wet liquid at a second temperature different from the first temperature to a bottom surface of the rotating substrate.

14. The method of claim 13, wherein in the second pre-wet operation, the first temperature of the second pre-wet liquid supplied to the top surface of the substrate is the same as the temperature of the first pre-wet liquid.

15. The method of claim 1, further comprising:
a liquid film forming operation of supplying a wet liquid to the rotating substrate to form a liquid film, the liquid film forming operation being performed after the chemical treatment operation; and
a drying operation of supplying a supercritical fluid to the substrate on which the liquid film is formed to dry the substrate, the drying operation being performed after the liquid film forming operation.

16. A manufacturing method comprising:
a first pre-wet operation of supplying heated isopropyl alcohol to a patterned wafer to pre-wet the wafer;
after the first pre-wet operation, a second pre-wet operation of supplying room temperature isopropyl alcohol or deionized water to the wafer;
after the second pre-wet operation, a chemical treatment operation of supplying a chemical to the wafer; and
a drying operation of drying the wafer by supplying supercritical fluid to the wafer on which the chemical treatment operation has been performed.

17. The manufacturing method of claim 16, wherein the chemical is selected from a substance containing a sulfuric acid component, a substance containing ammonia water, a substance containing a hydrofluoric acid component, or a substance containing a phosphoric acid component.

18.-20. (canceled)
